(19) United States
(12) Patent Application Publication
(10) Pub. No.: US 2013/0087196 A1
(43) Pub. Date: Apr. 11, 2013

(54) Photonic Energy Concentrators Arranged on Plural Levels

(71) Applicant: Karl S. Weibezahn, Corvallis, OR (US)

(72) Inventor: Karl S. Weibezahn, Corvallis, OR (US)

(21) Appl. No.: 13/270,063

(22) Filed: Oct. 10, 2011

(51) Int. Cl. H01L 31/0232; F24J 2/04; F24J 2/38

(52) U.S. Cl. 136/259; 126/600; 126/634

(57) ABSTRACT

Apparatus and methods related to solar energy are provided. Light concentrators are mechanically coupled and arranged as respective groups within a system. Groups are disposed along upper and lower levels. Lower level groups are aligned with respective gaps defined between upper level groups. Angular positioning of the light concentrators tracks the motion of the sun, resulting in varying gap widths. Light concentrators on the lower level receive varying amounts of sunlight accordingly, yet contribute to the overall energy yield from the system.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Photovoltaic cells are solid-state devices that directly convert incident photonic energy, such as sunlight, into electrical energy. Other types of systems heat or boil water or other fluid media using solar radiation. Improvements to such devices and related systems are continuously sought after. The present teachings address the foregoing concerns.

### BRIEF DESCRIPTION OF THE DRAWINGS

The present embodiments will now be described, by way of example, with reference to the accompanying drawings, in which:

FIG. 1 depicts an isometric-like view of a double-curvature photonic energy concentrator as contemplated under the present teachings;

FIG. 2 depicts an isometric-like view of trough-like solar energy device according to the present teachings;

FIG. 3A depicts an end elevation view of an arrangement of light concentrators in a first operating state according to the present teachings;

FIG. 3B depicts the arrangement of light concentrators of FIG. 3A in a second operating state according to the present teachings;

FIG. 3C depicts the arrangement of light concentrators of FIG. 3A in a third operating state according to the present teachings;

FIG. 4 depicts a block diagram of a system according to the present teachings;

FIG. 5 depicts a flow diagram of a method according to the present teachings.

### DETAILED DESCRIPTION

### Introduction

Apparatus and methods related to solar energy are provided. Light concentrators are arranged as respective groups and mechanically coupled for angular positioning in unison, such that a system is defined. Respective groups are disposed along upper and lower levels. Lower level groups are aligned with respective gaps defined between upper level groups. Angular positioning of the light concentrators follows the motion of the sun, resulting in varying gap widths between the upper-level groups. Light concentrators on the lower level receive varying amounts of sunlight accordingly, yet contribute to the overall energy yield from the system.

In one example, a device includes a housing and a plurality of first light concentrators arranged along a first level within the housing. The first light concentrators are configured to be angularly positioned in accordance with an apparent position of the sun. The device also includes a plurality of second light concentrators arranged along a second level within the housing and beneath the first level. The second light concentrators are configured to be angularly positioned in accordance with an apparent position of the sun. The second light concentrators are disposed so as to receive radiant photonic energy that varies in accordance with the angular position of the first light concentrators.

In another example, a system includes first concentrators arranged as two or more groups along a first level. The first concentrators are configured to be angularly positioned in accordance with a source of radiant photonic energy. The system also includes second concentrators arranged as one or more groups along a second level beneath the first level. The second concentrators are configured to be angularly positioned in accordance with a source of radiant photonic energy. Each group of second concentrators is aligned with a respective gap defined between two adjacent groups of the first concentrators. The system additionally includes a plurality of target entities disposed to receive concentrated photonic energy from respective ones of the first and second concentrators. Each of the target entities is configured to provide electrical or thermal energy to a load. The system further includes a housing disposed about the first and second concentrators.

In yet another example, a method includes angularly positioning a plurality of light concentrators in accordance with an apparent position of the sun. The light concentrators are arranged as respective groups along an upper level and a lower level beneath the upper level. The method also includes receiving at least some sunlight at a group disposed on the lower level and aligned with a gap defined between two groups on the upper level. The method further includes providing at least thermal energy or electrical energy to a load entity by way of the light concentrators.

### Illustrative Double-Curved Concentrator

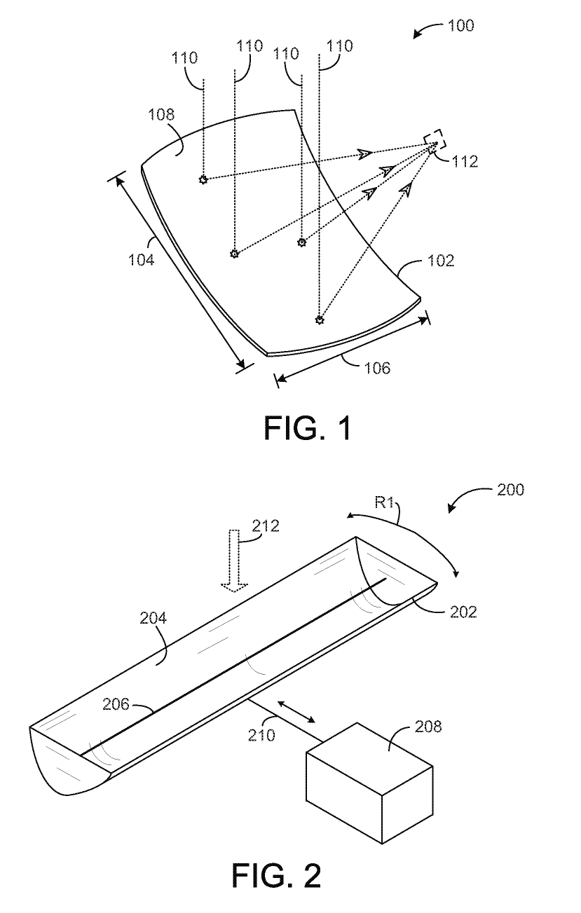

Reference is now made to FIG. 1, which depicts an isometric-like view of a photonic energy concentrator (concentrator) 100. The concentrator 100 is illustrative and non-limiting with respect to the present teachings. Other concentrators, devices and systems are also contemplated and can be used.

The concentrator 100 is formed from a sheet material 102. The sheet material 102 can be defined by or include thermoplastic, metal, or another suitable material. The sheet material 102 is characterized by a first parabolic curvature along a lengthwise aspect 104. The sheet material 102 is also characterized by a second parabolic curvature along a widthwise aspect 106. The concentrator 100 is therefore characterized by a dual parabolic curvature. The concentrator 100 is therefore referred to as a double-curvature concentrator 100 for purposes of the present teachings.

The concentrator 100 also includes a surface treatment 108 on the concave side or “face” of the sheet material 102. In one example, the surface treatment 108 is reflective in nature. In another example, the surface treatment 108 is made up of one or more dichroic materials. Such surface treatment 108 can be defined by or include one or more layers of aluminum, silver, silicon dioxide (SiO₂), titanium dioxide (TiO₂), niobium dioxide (NbO₂), or other suitable materials or compounds.

The concentrator 100 is configured to concentrate incident photonic energy—illustrated by four respective light rays 110—onto a spot-like target location 112. Thus, the double-curvature concentrator 100 functions to concentrate light onto a relatively small region.

### Second Illustrative Device

Attention is now turned to FIG. 2, which depicts an isometric-like view of a device 200. The device 200 is illustrative and non-limiting in nature. Thus, other devices, apparatus and systems are contemplated by the present teachings. The device 200 is also referred to as a solar energy device 200 for purposes herein.

The device 200 includes a light concentrator (concentrator) 202. The concentrator 202 can be formed from thermoplastic, plastic, fiberglass, metal or another suitable material. The concentrator 202 is characterized by an elongated trough-like form-factor and having a parabolic cross-sectional shape. The concentrator 202 includes a reflective surface treatment 204. In one example, the reflective surface treatment 204 is defined by a layer of aluminum metal overlaid with a protective layer of silicon dioxide. Other surface treatments 204 can also be used. The concentrator 202 is also referred to as a parabolic trough 202 for purposes herein.

The concentrator 202 is configured to concentrate photonic energy (e.g., sunlight) along a strip-like target location 206 by virtue of the reflective surface treatment 204 and the parabolic cross-sectional shape. In one example, a target entity defined by a fluid conduit is disposed along the target location 206. In another example, one or more photovoltaic (PV) cells are disposed along the target location 206. Other examples having other respective target entities can also be used.

The device 200 also includes a positioner 208 mechanically coupled to the concentrator 202 by way of a linkage 210. The positioner 208 is configured to angularly position (i.e., pivot, or rotate) the concentrator 202 within an arc-like range “R1”. The positioner 208 is further configured such that the angularly positioning is performed in accordance with an apparent position of the sun as it traverses the sky during daylight hours. In this way, the positioner 208 and the linkage 210 cause the concentrator 202 to follow or “track” a source of radiant photonic energy 212 (i.e., sunlight) during normal typical operations.

The device 200 is illustrative of a photonic energy concentrator that can be used with photovoltaic cells, thermal-absorption piping, or other target entities. An illustrative reflective surface treatment 204 is described above. In another example, the surface treatment 204 is defined by one or more layers of dichroic material(s) such that a selected spectral portion of incident light energy is concentrated onto the target location 206. Operating characteristics of the target entities (e.g., PV cells) can be selected in accordance with the concentrated spectral content in such an embodiment.

### Illustrative Light Concentrator Arrangement

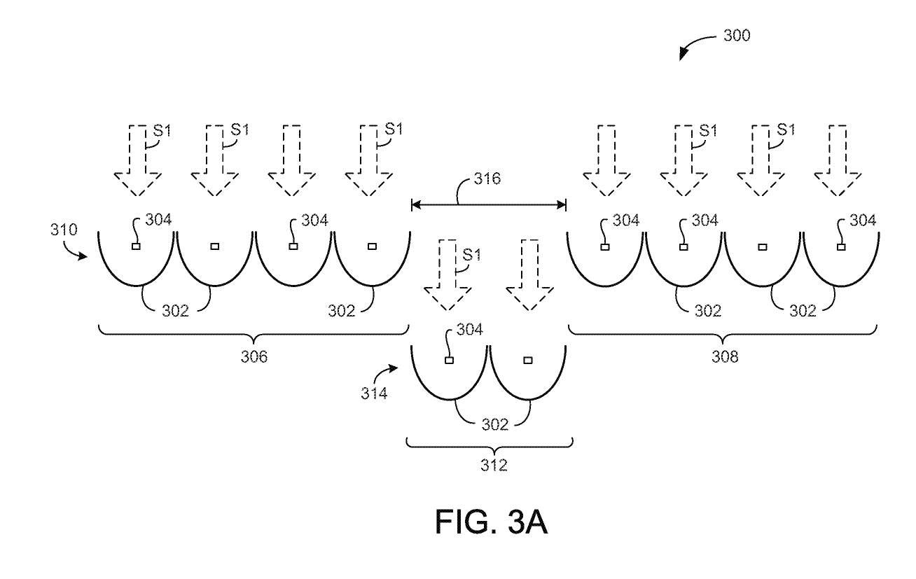

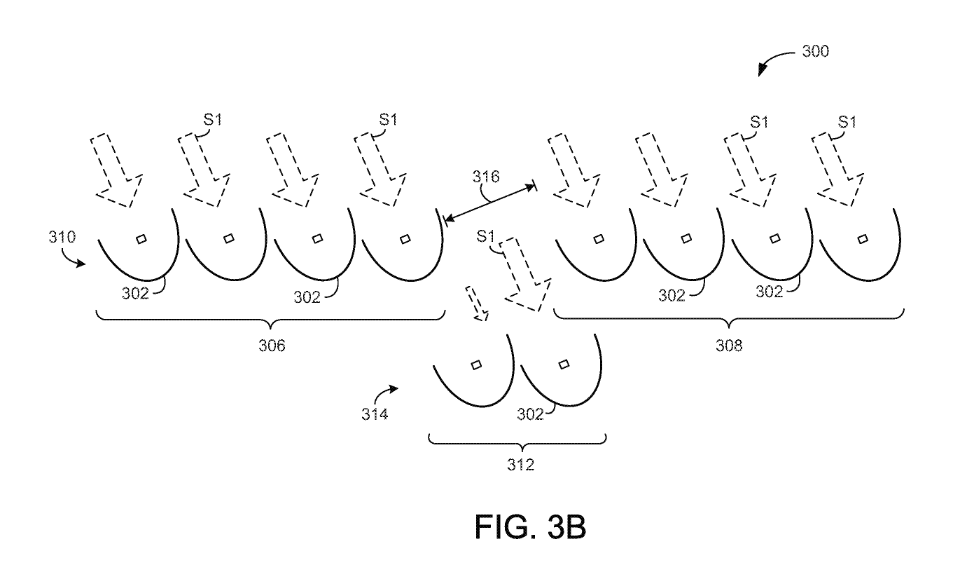

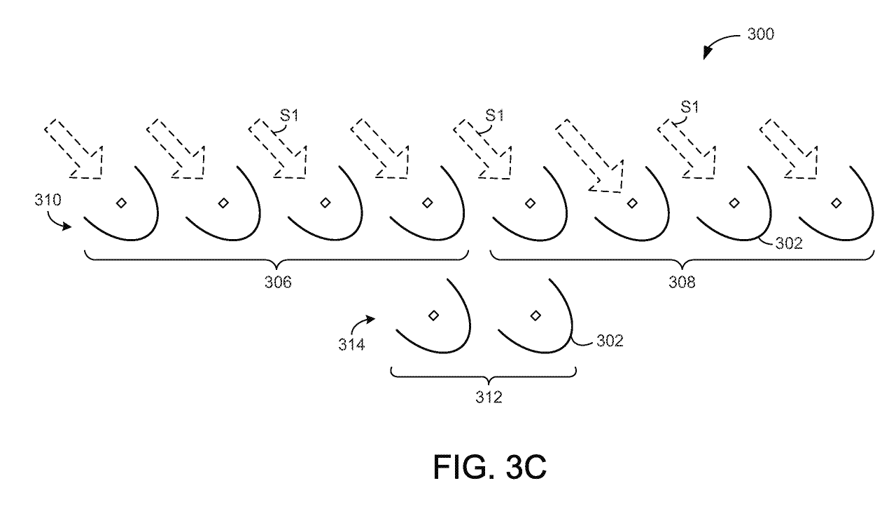

Reference is now directed to FIGS. 3A, 3B and 3C, which depict respective end elevation views of an arrangement 300 of light concentrators in distinct operating states or orientations. The arrangement 300 is illustrative and non-limiting in nature. Thus, other devices, apparatus and systems are contemplated by the present teachings.

In regard to FIG. 3A, the arrangement 300 includes a plurality of light concentrators 302. Each light concentrator (concentrator) 302 can be formed from any suitable material and is defined by a parabolic or semi-parabolic cross-sectional shape. Thus, each concentrator 302 is also referred to as a parabolic trough 302. Other concentrators having other cross-sectional shapes can also be used. As depicted in FIG. 3A, all of the concentrators 302 are in an upright or 90-degree angular orientation. Such an orientation can correspond to a noon position of the sun in the sky.

Each concentrator 302 also includes a reflective or dichroic surface treatment configured to concentrate incident photonic energy (e.g., sunlight) “S1” onto a respective target location 304. In one example, the surface treatment of each concentrator 302 is defined by a thin layer of aluminum over-coated by a protective layer of silicon dioxide. Other surface treatments can also be used.

The concentrators 302 are arranged and mechanically coupled so as to define a group 306 and a group 308 spaced apart from each other and disposed along a first or upper level 310, The concentrators 302 are further arranged to define a group 312 on a second or lower level 314. The group 312 is located beneath and in alignment with a gap 316 defined between the groups 306 and 308. Thus, the respective concentrators 302 of the group 312 are fully exposed to sunlight S1 through the gap 316 and by virtue of their 90-degree angular orientations. The gap 316 can also be referred to as a light passage window for purposes herein.

Turning attention now to FIG. 3B, the light concentrators 302 are all in a 67-degree angular orientation, corresponding to a mid-morning (or mid-afternoon) position of the sun in the sky. It is noted that the concentrators 302 are evenly spaced, yet spread apart such that the groups 306, 308 and 312 occupy respectively greater widths relative to those of FIG. 3A. In turn, the gap 316 is reduced in width relative to that of FIG. 3A as a result of the widened distribution within the groups 306 and 308.

The light concentrators 302 of the group 312 are now partially obscured and receive reduced sunlight S1 relative to that depicted in FIG. 3A. Thus, the angular orientation depicted in FIG. 3B results in less than full sunlight S1 exposure for those concentrators 302 disposed on the lower level 314.

Reference is now made to FIG. 3C, wherein the light concentrators 302 are all in a 45-degree angular orientation, corresponding to an early morning (or late afternoon) position of the sun in the sky. It is noted that the concentrators 302 within the respective groups 306 and 308 are evenly spaced such that the gap 316 is reduced essentially to nothing (and therefore is not depicted).

The light concentrators 302 of the group 312 are now totally obscured from receiving any sunlight S1 due to the side-by-side distribution of the light concentrators 302 along the upper level 310. The angular orientation depicted in FIG. 3C results in (about) zero sunlight S1 exposure for those concentrators 302 disposed on the lower level 314.

The arrangement 300 is described above with respect to three different operating orientations. It is to be understood that the respective light concentrators 302 can be angularly positioned in a continuous or discrete (i.e., step-wise) manner over a 90-degree range, from +45 degrees to −45 degrees of tilt. Additionally, the concentrators 302 along the lower level 314 operate to capture varying amounts of sunlight S1 depending on the instantaneous angular orientation of those on the upper level 310. As a result, the concentrators 302 of the lower level 314 contribute to the overall energy yield of the arrangement 300 during typical normal operations.

### Illustrative System Block Diagram

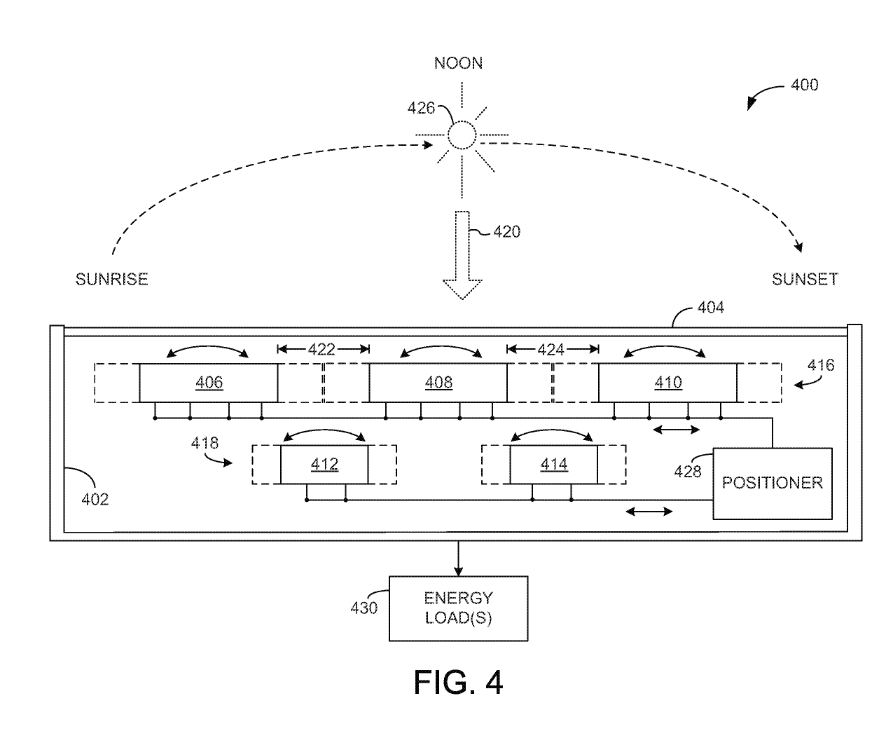

Attention is now directed to FIG. 4, which depicts a block diagram of a system 400 according to the present teachings. The system 400 is illustrative and non-limiting in nature, and other systems, devices and apparatus can be defined and used according to the present teachings. The system 400 is intended to illustrate the present teachings in a generalized format, and is neither exhaustive nor limiting in that respect.

The system 400 includes a housing 402. The housing 402 can be formed from thermoplastic, fiberglass, metal, and so on. The housing 402 is disposed generally beneath and about groups of respective light concentrators as described below. The system 400 also includes a transparent cover 404. The transparent cover 404 can be formed from glass, plastic, acrylic, or another suitable material. The transparent cover 404 protects the elements contained within the housing 402 against potentially damaging factors such as snow, rain, wind blown dust and so on during normal use.

The system 400 includes a plurality of light concentrators (e.g., 302) mechanically coupled and arranged as five respective groups 406, 408, 410, 412 and 414. In particular, the groups 406, 408 and 410 are arranged along an upper level 416, The groups 412 and 414 arranged along a lower level 418. Each of the light concentrators within the respective groups 406-414 bears a reflective or dichroic surface treatment (e.g., 204) and includes formed surface area such that incident photonic energy 420 becomes concentrated onto one or more targets (e.g., 304). The groups 412 and 414 are disposed below and in alignment with respective gaps 422 and 424 defined between the groups 406-408 and 408-410, respectively.

Each of the groups 406-414 is angularly positionable in accordance an apparent position of the sun 426 in the sky. Each of the groups 406-414 expands or contracts along its corresponding level 416 or 418 in accordance with the angular positioning of the light concentrators. As a result, the light concentrators within the groups 412 and 414 are disposed to receive varying amounts of sunlight 420 during the course of a typical operating day.

The system 400 also includes a positioner 428. The positioner 428 can include any electronic, mechanical or other constituency as required for angularly positioning the light concentrators of the groups 406-414 as the sun 426 traverses the sky during a normal operating day. The positioner 428 can thus include, without limitation, light detecting circuitry, one or more microprocessors or microcontrollers, electromechanical servos, and so on.

The system 400 further includes one or more energy loads 430 coupled to receive thermal, electrical or other energy from the respective targets (e.g., 304) of the light concentrator groups 406-414. Non-limiting examples of such energy loads 430 include thermal storage mass, heat exchangers, thermal fluid circulating systems, storage batteries, electrical power conditioning circuitry, a computer, a radio transceiver, a power inverter, and so on. In one example, photovoltaic cells of the groups 406-414 provide electrical energy to an electronic load 430. In another example, fluid-filled conduits of the groups 406-414 provide thermal energy to a heat exchanger/thermal load 430. Other examples can also be used.

The system 400 generally depicts a solar energy system having a plurality of light concentrators operably supported within a panel-like housing 402. A positioner 428 angularly positions or manipulates the light concentrators as respective groups 406-414 in accordance with an apparent position of the sun 426. Photonic energy is concentrated on respective target entities of the groups 406-414 and thermal and/or electrical energy is provided to one or more loads 430.

### Illustrative Method

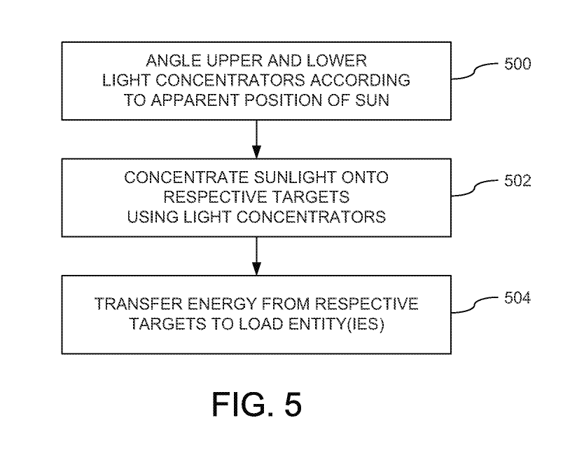

Reference is now made to FIG. 5, which depicts a flow diagram of a method according to another example of the present teachings. The method of FIG. 5 includes particular steps and proceeds in a particular order of execution. However, it is to be understood that other respective methods including other steps, omitting one or more of the depicted steps, or proceeding in other orders of execution can also be used. Thus, the method of FIG. 5 is illustrative and non-limiting with respect to the present teachings. Reference is also made to FIGS. 3A-3C and 4 in the interest of understanding the method of FIG. 5.

At 500, light concentrators arranged along upper and lower levels are angularly positioned according to an apparent position of the sun. For purposes of a present illustration, respective light concentrators 302 are arranged along an upper level 310 and a lower level 314. The light concentrators 302 are angularly positioned so as to receive incident sunlight S1.

At 502, sunlight is concentrated onto respective targets by the light concentrators. For purposes of the present example, solar energy (photonic energy) is concentrated onto respective targets 304 by the light concentrators 302. Such targets 304 are further understood to be respective photovoltaic cells configured to provide electrical energy by direct conversion of the concentrated sunlight. Other targets can be used in other examples.

At 504, energy is transferred from the respective targets to a load entity or entities. For purposes of the present example, electrical energy is transferred from the target entities (PV cells) 304 to an electrical storage battery 430. This operation is maintained over the course of a normal operating day, the respective light concentrators being angularly positioned in unison so as to track the apparent motion of the sun.

In general and without limitation, the present teachings contemplate light concentrators usable in solar energy systems and other applications. The light concentrators are arranged such that respective groups or sets are defined along two levels, one overlying the other. Each group of light concentrators on the lower level is aligned with a gap or light passage window defined between two adjacent groups on the upper level. Each light concentrator configured to concentrate photonic energy, such as sunlight, onto a respective target entity or entities.

The individual light concentrators are angularly positioned or tilted, in unison, so as to track or follow the apparent motion of the sun across the sky. The angle of the light concentrators determines the amount spread or distribution of those within a group, such that the group as a whole occupies a varying lateral spread along the corresponding level. The gaps between adjacent groups expand and contract in accordance with angle-based distribution of the light concentrators along that level.

In turn, the light concentrators along the lower level receive varying amounts of sunlight (or other photonic exposure) depending on the instantaneous angular positioning of the overall system. In general, little or no sunlight is received during times of extreme tilt (i.e., early morning or late afternoon), with maximum sunlight being received at time of 90-degree tilt (i.e., noon), at the lower level. The light concentrators along the lower level harvest additional energy, resulting in a greater overall yield compared to systems having a single level of concentrator distribution.

Various two-level systems of light concentrators as contemplated by the present teachings can be packaged in panel-like form factors. A positioner can be integrated within such packaging, or coupled to the light concentrators from outside by appropriate linkage. Thermal loads, electrical loads or other applications can be correspondingly served.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A device, comprising:
a housing;
a plurality of first light concentrators arranged along a first level within the housing, the first light concentrators configured to be angularly positioned in accordance with an apparent position of the sun; and
a plurality of second light concentrators arranged along a second level within the housing beneath the first level, the second light concentrators configured to be angularly positioned in accordance with an apparent position of the sun, the second light concentrators disposed so as to receive radiant photonic energy varying in accordance with the angular position of the first light concentrators.

2. The device according to claim 1, first light concentrators arranged as two or more groups along the first level, the second light concentrators arranged as at least one group along the second level, each group of second light concentrators aligned with a respective gap defined between adjacent groups of the first light concentrators.

3. The device according to claim 2, each gap varying in width in accordance with an angular positioning of the first light concentrators.

4. The device according to claim 2, the first light concentrators within each group being mechanically coupled so as to maintain about uniform spacing regardless of angular positioning.

5. The device according to claim 1, at least one of the first light concentrators or the second light concentrators configured to concentrate photonic energy onto a photovoltaic cell, or a fluid conduit.

6. The device according to claim 1, at least one of the first or second light concentrators formed to define a parabolic trough so as to concentrate photonic energy onto a strip-like target location.

7. The device according to claim 1, at least one of the first or second light concentrators defined by a first parabolic curvature and a second parabolic curvature orthogonal to the first parabolic curvature so as to concentrate photonic energy onto a spot-like target location.

8. The device according to claim 1 further comprising a positioner to angularly position at least the first light concentrators in unison in accordance with an apparent position of the sun.

9. A system, comprising:
first concentrators arranged as two or more groups along a first level, the first concentrators configured to he angularly positioned in accordance with a source of radiant photonic energy;
second concentrators arranged as one or more groups along a second level beneath the first level, the second concentrators configured to be angularly positioned in accordance with a source of radiant photonic energy, each group of second concentrators aligned with a respective gap defined between two adjacent groups of the first concentrators;
a plurality of target entities disposed to receive concentrated photonic energy from respective ones of the first and second concentrators, each of the target entities configured provide electrical or thermal energy to a load; and
a housing disposed about the first and second concentrators.

10. The system according to claim 9, the first concentrators within each group being mechanically linked so as to maintain about uniform spacing between adjacent ones of the first concentrators.

11. The system according to claim 9, the housing defined by a panel like form-factor having the first and second concentrators disposed within.

12. The system according to claim 9 further comprising a load to receive at least thermal or electrical energy from one or more of the target entities

13. The system according to claim 9, at least one of the target entities including a photovoltaic cell, or a fluid conduit.

14. The system according to claim 9 further comprising a positioner configured to angularly position at least one of the first concentrators or the second concentrators in accordance with an apparent position of the sun.

15. The system according to claim 9, the gap defined between adjacent groups of first concentrators varying in width in accordance with the angular positioning of the first concentrators.

16. A method, comprising:
angularly positioning a plurality of light concentrators in accordance with an apparent position of the sun, the light concentrators arranged as respective groups along an upper level and a lower level beneath the upper level;
receiving at least some sunlight at a group disposed on the lower level and aligned with a gap defined between two groups on the upper level; and
providing at least thermal energy or electrical energy to a bad entity by way of the light concentrators.
